(19) United States
(12) Patent Application Publication
(10) Pub. No.: US 2007/0218698 A1
(43) Pub. Date: Sep. 20, 2007

(54) PLASMA ETCHING METHOD, PLASMA ETCHING APPARATUS, AND COMPUTER-READABLE STORAGE MEDIUM

(75) Inventor: Ryoichi YOSHIDA, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/682,935

(22) Filed: Mar. 7, 2007

Related U.S. Application Data
(60) Provisional application No. 60/786,027, filed on Mar. 27, 2006.

(30) Foreign Application Priority Data
Mar. 16, 2006 (JP) 2006-072683

(51) Int. Cl. H01L 21/465; C23F 1/00

(52) U.S. Cl. 438/710; 156/345.43; 156/345.29; 156/345.24; 438/738

(57) ABSTRACT

A plasma etching method includes the step of performing a plasma etching on a SiCN layer, which is formed on a substrate to be processed having a SiOCH layer and the SiCN layer, by using a plasma of an etching gas. A gaseous mixture including CF₄ and NF₃ is employed as the etching gas, and the SiCN layer is selectively etched against the SiOCH layer. In the plasma etching method, a selectivity of the SiCN layer against the SiOCH layer (an etching rate of the SiCN layer/an etching rate of the SiOCH layer) is equal to or greater than about 1.1 and a flow rate ratio of the NF₃ to the CF₄ is equal to or greater than about 6%.

### FIELD OF THE INVENTION

The present invention relates to a plasma etching method for selectively etching a SiCN layer against a SiOCH layer; and also relates to a plasma etching apparatus and a computer-readable storage medium to be used therefor.

### BACKGROUND OF THE INVENTION

Conventionally, a plasma etching for performing an etching by using a plasma generated from an etching gas has been widely employed in a manufacturing process of semiconductor devices. To form, e.g., via holes or trenches on an interlayer insulating film made of a low-k film by the plasma etching, there is known a technique of forming an underlying SiCN layer and using the SiCN layer as an etching stopper layer. Further, there is also known a method of performing a plasma etching on the SiCN layer by using an etching gas made up of only a CF₄ gas (see, for example, Japanese Patent Laid-open Application No. 2005-33168).

In a liner removal step (LRS) for removing the SiCN layer serving as the etching stopper layer by the plasma etching, it is preferable to selectively plasma-etch the SiCN layer against a SiOCH layer which is used as an interlayer insulating film.

However, in the plasma etching using the etching gas made up of only the CF₄ gas, an etching rate ratio (selectivity) of the SiCN layer to the SiOCH layer is just estimated to be about 0.8, so there occurs a problem that a considerable amount of SiOCH layer is etched unintentionally during the etching of the SiCN layer.

### SUMMARY OF THE INVENTION

It is, therefore, an object of the present invention to provide a plasma etching method capable of improving a selectivity of SiCN against SiOCH compared with the prior art; and also to provide a plasma etching apparatus for performing the plasma etching method and a computer-readable storage medium to be used therefor.

In accordance with a first aspect of the present invention, there is provided a plasma etching method including the step of: performing a plasma etching on a SiCN layer, which is formed o n a substrate to be processed having a SiOCH layer and the SiCN layer, by using a plasma of an etching gas, wherein a gaseous mixture including CF₄ and NF₃ is employed as the etching gas, and the SiCN layer is selectively etched against the SiOCH layer.

In accordance with a second aspect of the present invention, there is provided the plasma etching method comprising the step of: performing a plasma etching on a SiCN layer, which is formed on a substrate to be processed having a SiOCH layer provided with a trench and a via hole by using a plasma of an etching gas, the SiCN layer, to be used as an etching stopper layer, being formed under the SiOCH layer, wherein a gaseous mixture including CF₄ and NF₃ is employed as the etching gas, and the SiCN layer is selectively etched against the SiOCH layer.

It is preferable that a selectivity of the SiCN layer against the SiOCH layer (an etching rate of the SiCN layer/an etching rate of the SiOCH layer) is equal to or greater than about 1.1.

It is preferable that a flow rate ratio of the NF₃ to the CF₄ is equal to or greater than about 6%.

It is preferable that the plasma etching is performed by using a plasma etching apparatus including a processing chamber in which a lower electrode for mounting the substrate to be processed thereon and an upper electrode disposed to face the lower electrode, by applying a first high frequency power for plasma generation to the upper or the lower electrode while applying a second high frequency power for ion induction to the lower electrode, wherein a frequency of the second high frequency power is lower than that of the first high frequency power, and the second high frequency power applied to the lower electrode is set to be equal to or lower than about 0.42 W/cm².

In accordance with a third aspect of the present invention, there is provided a plasma etching apparatus including: a processing chamber for accommodating therein a semiconductor substrate to be processed; a processing gas supply unit for supplying an etching gas into the processing chamber; a plasma generating unit for converting the etching gas supplied from the processing gas supply unit into a plasma, thereby plasma processing the semiconductor substrate; and a control unit for controlling the above-mentioned plasma etching method to be carried out in the processing chamber.

In accordance with a fourth aspect of the present invention, there is provided a computer-readable storage medium for storing therein a computer executable control program, wherein the control program controls the plasma processing apparatus to perform the above-mentioned plasma etching method.

In accordance with the present invention, it is possible to provide a plasma etching method capable of improving a selectivity of SiCN against SiOCH compared with the prior art; and also to provide a plasma etching apparatus for performing the plasma etching method and a computer-readable storage medium to be used therefor.

### BRIEF DESCRIPTION OF THE DRAWINGS

The above and other objects and features of the present invention will become apparent from the following description of embodiments given in conjunction with the accompanying drawings, in which:

FIGS. 1A and 1B provide cross sectional views of a semiconductor wafer to which a plasma etching method in accordance with an embodiment of the present invention is applied;

FIG. 2 sets forth a schematic configuration view of a plasma etching apparatus in accordance with the embodiment of the present invention; and

FIG. 3 presents a graph showing a relationship between a NF₃ flow rate and a SiCN/SiOCH selectivity.

### DETAILED DESCRIPTION OF THE EMBODIMENTS

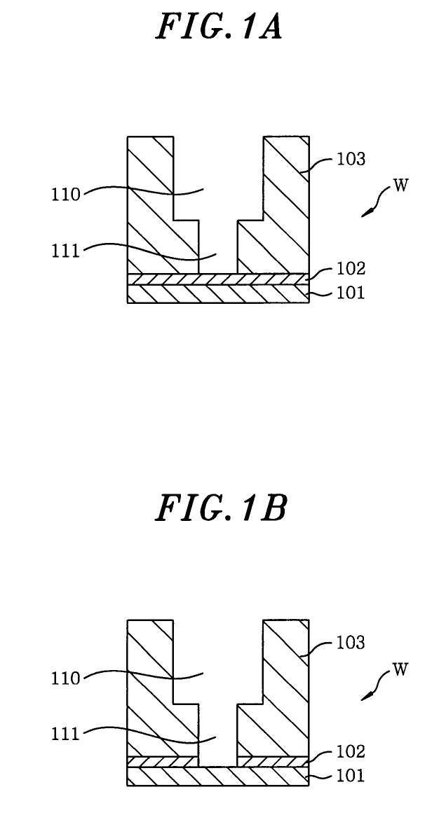

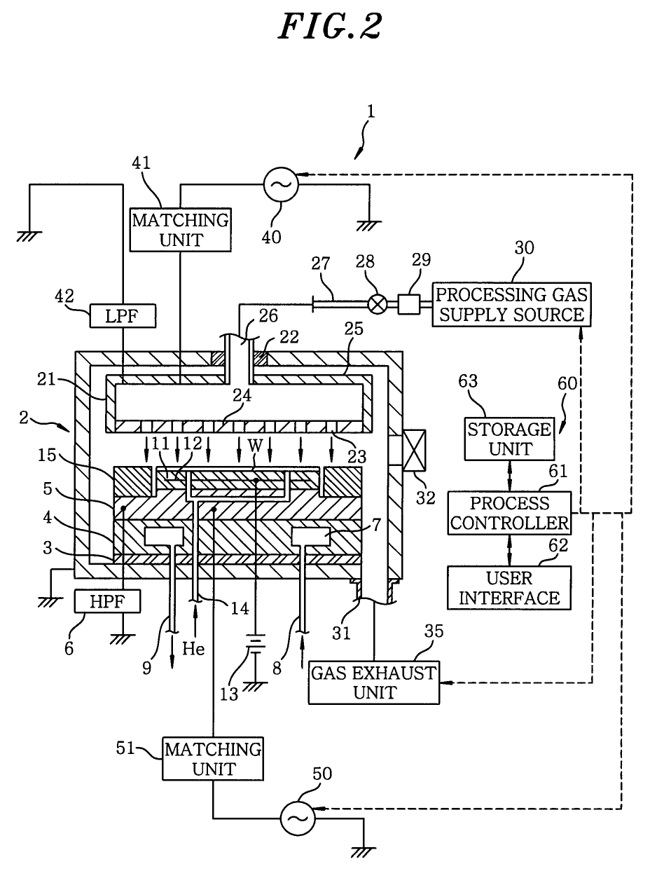

Hereinafter, an embodiment of the present invention will be described in detail with reference to the accompanying drawings. FIGS. 1A and 1B are enlarged cross sectional configuration views of a semiconductor wafer W which is used in a plasma etching method in accordance with an embodiment of the present invention. FIG. 2 illustrates a configuration of a plasma etching apparatus in accordance with the embodiment of the present invention. Below, the configuration of the plasma etching apparatus will be first explained with reference to FIG. 2.

The plasma etching apparatus 1 is configured as a capacitively coupled parallel plate type etching apparatus having an upper and a lower electrode plate placed to face each other in parallel and respectively connected to power supplies for plasma generation.

The plasma etching apparatus 1 has a cylindrical processing chamber (processing vessel) 2 formed of, for example, aluminum whose surface is anodically oxidized, and the processing chamber 2 is grounded. A substantially columnar susceptor support 4 for mounting thereon a target object to be processed, e.g., a semiconductor wafer W is installed at a bottom portion of the processing chamber 2 via an insulating plate 3 such as ceramic. Further, a susceptor 5 serving as a lower electrode is mounted on the susceptor support 4, and the susceptor 5 is connected to a high pass filter (HPF) 6.

A coolant path 7 is formed inside the susceptor supoort 4 to introduce a coolant via a coolant introducing line 8 and discharge it via a coolant discharge line 9. By this circulation of the coolant, the cold heat of the coolant is transferred to the semiconductor wafer W via the susceptor 5, whereby the wafer W is maintained at a desired temperature level.

The susceptor 5 has an upper central portion of a disk shape, which protrudes higher than its peripheral portion, and an electrostatic chuck 11 that is shaped substantially identical to the semiconductor wafer W is disposed on the upper central portion of the susceptor 5. The electrostatic chuck 11 includes an electrode 12 embedded in an insulating member. The semiconductor wafer W is electrostatically attracted and held by the electrostatic chuck 11 by, for example, a Coulomb force generated by applying a DC voltage of, for example, 1.5 kV to the electrode 12 from a DC power supply 13 connected thereto.

Further, formed through the insulating plate 3, the susceptor support 4, the susceptor 5 and the electrostatic chuck 11 is a gas channel 14 for supplying a heat transfer medium (for example, a He gas) to the rear surface of the semiconductor wafer W. The cold heat of the susceptor 5 is transferred from the susceptor 5 to the semiconductor wafer W through the heat transfer medium, so that the wafer W is maintained at the specific temperature level.

An annular focus ring 15 is disposed on the periphery of the top surface of the susceptor 5 to surround the semiconductor wafer W loaded on the electrostatic chuck 11. The focus ring 15 is formed of a conductive material such as silicon and serves to improve etching uniformity.

An upper electrode 21 is disposed above the susceptor 5, while facing it in parallel. The upper electrode 21 is supported at an upper portion of the processing chamber 2 via an insulating member 22. The upper electrode 21 includes an electrode plate 24; and an electrode support 25 that serves to support the electrode 24 and is made up of a conductive material. The electrode plate 24 is formed of a conductor or a semiconductor such as Si and SiC and is provided with a number of injection openings 23. The electrode plate 24 is configured to face the susceptor 5.

A gas inlet port 26 is formed at a center of the electrode support 25 of the upper electrode 21, and a gas supply line 27 is coupled to the gas inlet port 26. Further, the gas supply line 27 is connected to a processing gas supply source 30 via a valve 28 and a mass flow controller 29. The processing gas supply source 30 supplies an etching gas for a plasma etching.

A gas exhaust line 31 is connected to a bottom portion of the chamber 2 and coupled to a gas exhaust unit 35. The gas exhaust unit 35 includes a vacuum pump such as a turbo molecular pump and is configured to be capable of vacuum exhausting an inside of the processing chamber 2 to a depressurized atmosphere, e.g., down to a pressure of 1 Pa or less. Further, a gate valve 32 is installed at a sidewall of the processing chamber 2. The semiconductor wafer W is transferred between the processing chamber 2 and an adjacent load lock chamber (not shown) while the gate valve 32 is opened.

A first high frequency power supply 40 is connected to the upper electrode 21 via a matching unit 41. Further, a low pass filter (LPF) 42 is connected to the upper electrode 21. The first high frequency power supply 40 is of a frequency ranging from about 50 to 150 MHz. By applying a high frequency power in such a frequency range, a high-density plasma in a desirable dissociated state can be generated in the processing chamber 2.

Further, a second high frequency power supply 50 is connected to the susceptor 5 serving as the lower electrode via a matching unit 51. The second high frequency power supply 50 has a frequency range lower than that of the first high frequency power supply 40. By applying such a frequency range, a proper ionic action can be facilitated without causing any damage on the semiconductor wafer W serving as a target object to be processed. Preferably, the frequency of the second high frequency power supply 50 is determined within a range from about 1 to 20 MHz.

The whole operation of the plasma processing apparatus 1 having the above-described configuration is controlled by a control unit 60. The control unit 60 includes a process controller 61 having a CPU for controlling each component of the plasma etching apparatus 1; a user interface 62; and a memory 63.

A user interface 62 includes a keyboard for a process manager to input a command to operate the plasma etching apparatus 1, a display for showing an operational status of the plasma etching apparatus 1 and the like.

Moreover, the memory 63 stores therein, e.g., control programs (software) and recipes including processing condition data and the like to be used in realizing various processes, which are performed in the plasma etching apparatus 1 under the control of the process controller 61. When a command is received from the user interface 62, the process controller 61 retrieves a necessary recipe from the memory 63 as required to execute the command to perform a desired process in the plasma processing apparatus 1 under the control of the process controller 61. The recipe such as the control program or the processing condition data can be retrieved from a computer-readable storage medium (for example, a hard disk, a CD, a flexible disk, a semiconductor memory, or the like), or also can be transmitted on-line from another apparatus via, e.g., a dedicated line, when necessary.

When performing a plasma etching on the semiconductor wafer W by using the plasma etching apparatus 1 having the above-described configuration, the gate valve 32 is first opened, and the semiconductor wafer W is loaded into the processing chamber 2 from the load lock chamber (not shown) and mounted on the electrostatic chuck 11. Then, a DC voltage is applied to the electrostatic chuck 11 from the DC power supply 13, whereby the semiconductor wafer W is electrostatically attracted by the electrostatic chuck 11 to be held thereon. Subsequently, the gate valve 32 is closed, and the processing chamber 2 is vacuum evacuated to a specific vacuum level by the gas exhaust unit 35.

Thereafter, the valve 28 is opened, and an etching gas is supplied into a hollow space of the upper electrode 21 via the gas supply line 27 and the gas inlet port 26 from the processing gas supply source 30 while its flow rate is controlled by the mass flow controller 29. Then, the etching gas is discharged uniformly toward the semiconductor wafer W through the injection openings 23 of the electrode plate 24, as indicated by arrows in FIG. 2.

Then, the inner pressure of the processing chamber 2 is maintained at a specific pressure level, and a high frequency power of a specific frequency is applied to the upper electrode 21 from the first high frequency power supply 40, whereby a high frequency electric field is generated between the upper electrode 21 and the susceptor 5 serving as the lower electrode. As a result, the etching gas is dissociated and converted into plasma.

Meanwhile, a high frequency power of a frequency lower than that from the first high frequency power supply 40 is applied to the susceptor 5 serving as the lower electrode from the second high frequency power supply 50. As a result, ions among the plasma are attracted toward the susceptor 5, so that etching anisotropy is improved by ion assist.

Then, upon the completion of the plasma etching, the supply of the high frequency powers and the processing gas is stopped, and the semiconductor wafer W is retreated out of the processing chamber 2 in the reverse sequence as described above.

Below, the plasma etching method in accordance with the embodiment of the present invention will be described with reference to FIGS. 1A and 1B. As shown in FIG. 1A, on the surface of a semiconductor wafer W, which is a substrate to be processed, there are sequentially formed from a lower side a conductor layer 101 made of a metal such as copper, a SiCN layer 102 serving as an etching stopper layer, and a SiOCH layer 103 serving as an interlayer insulating film. Further, the SiOCH layer 103 is provided with a via hole 111 and a trench 110 formed therein. From this state, a plasma etching is performed on the SiCN layer 102 to remove it, so that a state shown in FIG. 1B is obtained.

As a first example, a plasma etching was performed on a semiconductor wafer W (having a diameter of 30 cm) configured as illustrated in FIG. 1A by using the plasma etching apparatus 1 shown in FIG. 2 according to a processing recipe to be specified below.

The processing recipe for each example described below was retrieved from the memory 63 of the control unit 60 and executed by the process controller 61. The process controller 61 controlled each component of the plasma etching apparatus 1 based on a control program, whereby an etching process was performed according to the retrieved recipe as follows:
etching gas: CF₄/NF₃=150/50 sccm;
pressure: 13.3 Pa (100 mTorr);
power (upper electrode/lower electrode): 450 W/300 W;
temperature (lower electrode/upper electrode/chamber sidewall): 40/60/60° C.;
distance between the upper and the lower electrode: 35 mm;
cooling He pressure (center portion/edge portion) 1995/5320 Pa (15/40 Torr);
etching time: 15 seconds.

As a result of the above plasma etching, an etching rate of the SiCN was 292 nm/min, while an etching rate of the SiOCH was 160 nm/min. Further, a selectivity of the SiCN against the SiOCH (the etching rate of the SiCN/the etching rate of the SiOCH) was estimated to be 1.8.

In a first comparative example, a plasma etching was performed under the same processing conditions as those of the first example excepting that an etching gas made up of only a CF₄ gas was employed instead of the etching gas of the first example which includes CF₄ and NF₃. As a result of performing the plasma etching in these conditions, etching rates of SiCN and SiOCH were 130 nm/min and 160 nm/min, respectively, and a SiCN/SiOCH selectivity (the etching rate of the SiCN/the etching rate of the SiOCH) was estimated to be 0.8. Thus, the SiCN/SiOCH selectivity of the first example was more than two times that of the first comparative example.

In a second and a third example, a plasma etching was performed under the same processing conditions as those of the first example, excepting that the flow rate of the NF₃ gas was reduced to 20 sccm and 10 sccm in the second and the third example, respectively. As a result of the second example (flow rate of NF₃=20 sccm), etching rates of SiCN and SiOCH were 238 nm/min and 160 nm/min, respectively, and a SiCN/SiOCH selectivity (the etching rate of the SiCN/the etching rate of the SiOCH) was estimated to be 1.5. Further, in the third example (flow rate of NF₃=10 sccm), etching rates of SiCN and SiOCH were and 162 nm/min and 132 nm/min, respectively, and the SiCN/SiOCH selectivity (the etching rate of the SiCN/the etching rate of the SiOCH) was estimated to be 1.2.

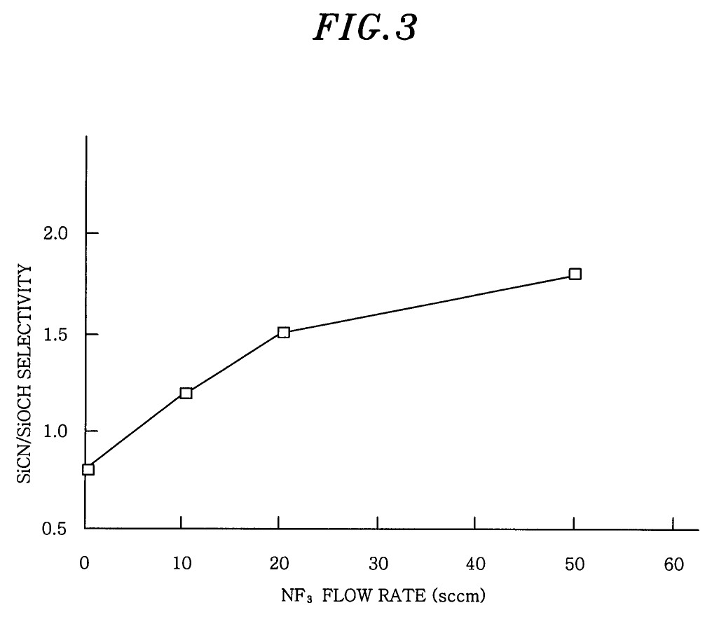

FIG. 3 provides a graph showing the results of the first to the third example and the comparative example. In the graph, the vertical axis represents the SiCN/SiOCH selectivity, while the horizontal axis indicates a NF₃ flow rate. As can be seen from the graph, the SiCN/SiOCH selectivity improves as the NF₃ flow rate is increased within the above-specified flow rate range. Further, it is preferable to set the NF₃ flow rate to be equal to or greater than 9 sccm so that the SiCN/SiOCH selectivity can be increased over 1 to become 1.1 or greater. If so, a flow rate ratio with respect to the CF₄ gas (150 sccm) becomes no smaller than 6%. Accordingly, it is preferable to set the flow rate ratio of the NF₃ to the CF₄ to be equal to or greater than 6%. Further, it more preferable to set the flow rate ratio to be equal to or grater than 7% to obtain a SiCN/SiOCH selectivity equal to or greater than 1.2.

In a second to a fourth comparative example, a plasma etching was performed under the same processing conditions as those of the first example excepting that N₂ (flow rate=150 sccm), CH₂F₂ (flow rate=10 sccm) and CO (flow rate=100 sccm) were employed instead of the NF₃ in the second to the fourth example, respectively. As a result, selectivities were estimated to be just 1.0 and could not be increased up to 1.1 or greater in all of the three comparative examples.

Further, a fourth example was conducted by performing a plasma etching under the following processing conditions:
etching gas: CF₄/NF₃=150/50 sccm;
pressure: 13.3 Pa (100 mTorr);
power (upper electrode/lower electrode): 450 W/200 W;
temperature (lower electrode/upper electrode/chamber sidewall): 40/60/60° C.;
distance between the upper and the lower electrode: 35 mm;
cooling He pressure (center/edge): 1995/5320 Pa (15/40 Torr);
etching time: 15 seconds.

The processing conditions of the fourth example are identical to those of the first example excepting that the power of the lower electrode is reduced from 300 W to 200 W. As a result of the fourth example, etching rates of SiCN and SiOCH were 190 nm/min and 60 nm/min, respectively, and a SiCN/SiOCH selectivity (the etching rate of the SiCN/the etching rate of the SiOCH) was estimated to be 3.2. From the result, it was confirmed that the selectivity improves when the power of the lower electrode is low to some extent. Accordingly, for a semiconductor wafer having a diameter of, e.g., 30 cm, it is preferable to set the power of the lower electrode to be equal to or lower than about 300 W (i.e., no greater than about 0.42 W/cm²) , and, more preferably, to be equal to or lower than about 200 W (i.e., no greater than about 0.28 W/cm²).

In accordance with the embodiment of the present invention as described above, a selectivity of SiCN against SiCN can be improved in comparison with conventional cases. Here, it is to be noted that the present invention is not limited to the embodiment as described above but can be modified in various ways. For example, the plasma etching apparatus is not limited to the parallel plate type plasma etching apparatus as shown in FIG. 2 in which high frequency powers are respectively applied to the upper and the lower electrode; but, instead, any of other various types of plasma etching apparatuses can be utilized.

While the invention has been shown and described with respect to the embodiment, it will be understood by those skilled in the art that various changes and modifications may be made without departing from the scope of the invention as defined in the following claims.

What is claimed is:

1. A plasma etching method comprising the step of:
performing a plasma etching on a SiCN layer, which is formed on a substrate to be processed having a SiOCH layer and the SiCN layer, by using a plasma of an etching gas,
wherein a gaseous mixture including CF₄ and NF₃ is employed as the etching gas, and the SiCN layer is selectively etched against the SiOCH layer.

2. A plasma etching method comprising the step of:
performing a plasma etching on a SiCN layer, which is formed on a substrate to be processed having a SiOCH layer provided with a trench and a via hole by using a plasma of an etching gas, the SiCN layer, to be used as an etching stopper layer, being formed under the SiOCH layer,
wherein a gaseous mixture including CF₄ and NF₃ is employed as the etching gas, and the SiCN layer is selectively etched against the SiOCH layer.

3. The plasma etching method of claim 1, wherein a selectivity of the SiCN layer against the SiOCH layer (an etching rate of the SiCN layer/an etching rate of the SiOCH layer) is equal to or greater than about 1.1.

4. The plasma etching method of claim 2, wherein a selectivity of the SiCN layer against the SiOCH layer (an etching rate of the SiCN layer/an etching rate of the SiOCH layer) is equal to or greater than about 1.1.

5. The plasma etching method of claim 1, wherein a flow rate ratio of the NF₃ to the CF₄ is equal to or greater than about 6%.

6. The plasma etching method of claim 2, wherein a flow rate ratio of the NF₃ to the CF₄ is equal to or greater than about 6%.

7. The plasma etching method of claim 3, wherein a flow rate ratio of the NF₃ to the CF₄ is equal to or greater than about 6%.

8. The plasma etching method of claim 4, wherein a flow rate ratio of the NF₃ to the CF₄ is equal to or greater than about 6%.

9. The plasma etching method of claim 1, wherein the plasma etching is performed by using a plasma etching apparatus including a processing chamber in which a lower electrode for mounting the substrate to be processed thereon and an upper electrode disposed to face the lower electrode, by applying a first high frequency power for plasma generation to the upper or the lower electrode while applying a second high frequency power for ion induction to the lower electrode, wherein a frequency of the second high frequency power is lower than that of the first high frequency power, and the second high frequency power applied to the lower electrode is set to be equal to or lower than about 0.42 W/cm².

10. The plasma etching method of claim 2, wherein the plasma etching is performed by using a plasma etching apparatus including a processing chamber in which a lower electrode for mounting the substrate to be processed thereon and an upper electrode disposed to face the lower electrode, by applying a first high frequency power for plasma generation to the upper or the lower electrode while applying a second high frequency power for ion induction to the lower electrode, wherein a frequency of the second high frequency power is lower than that of the first high frequency power, and the second high frequency power applied to the lower electrode is set to be equal to or lower than about 0.42 W/cm².

11. The plasma etching method of claim 3, wherein the plasma etching is performed by using a plasma etching apparatus including a processing chamber in which a lower electrode for mounting the substrate to be processed thereon and an upper electrode disposed to face the lower electrode, by applying a first high frequency power for plasma generation to the upper or the lower electrode while applying a second high frequency power for ion induction to the lower electrode, wherein a frequency of the second high frequency power is lower than that of the first high frequency power, and the second high frequency power applied to the lower electrode is set to be equal to or lower than about 0.42 W/cm².

12. The plasma etching method of claim 4, wherein the plasma etching is performed by using a plasma etching apparatus including a processing chamber in which a lower electrode for mounting the substrate to be processed thereon and an upper electrode disposed to face the lower electrode, by applying a first high frequency power for plasma generation to the upper or the lower electrode while applying a second high frequency power for ion induction to the lower electrode, wherein a frequency of the second high frequency power is lower than that of the first high frequency power, and the second high frequency power applied to the lower electrode is set to be equal to or lower than about 0.42 W/cm².

13. The plasma etching method of claim 5, wherein the plasma etching is performed by using a plasma etching apparatus including a processing chamber in which a lower electrode for mounting the substrate to be processed thereon and an upper electrode disposed to face the lower electrode, by applying a first high frequency power for plasma generation to the upper or the lower electrode while applying a second high frequency power for ion induction to the lower electrode, wherein a frequency of the second high frequency power is lower than that of the first high frequency power, and the second high frequency power applied to the lower electrode is set to be equal to or lower than about 0.42 W/cm².

14. The plasma etching method of claim 6, wherein the plasma etching is performed by using a plasma etching apparatus including a processing chamber in which a lower electrode for mounting the substrate to be processed thereon and an upper electrode disposed to face the lower electrode, by applying a first high frequency power for plasma generation to the upper or the lower electrode while applying a second high frequency power for ion induction to the lower electrode, wherein a frequency of the second high frequency power is lower than that of the first high frequency power, and the second high frequency power applied to the lower electrode is set to be equal to or lower than about 0.42 W/cm².

15. The plasma etching method of claim 7, wherein the plasma etching is performed by using a plasma etching apparatus including a processing chamber in which a lower electrode for mounting the substrate to be processed thereon and an upper electrode disposed to face the lower electrode, by applying a first high frequency power for plasma generation to the upper or the lower electrode while applying a second high frequency power for ion induction to the lower electrode, wherein a frequency of the second high frequency power is lower than that of the first high frequency power, and the second high frequency power applied to the lower electrode is set to be equal to or lower than about 0.42 W/cm².

16. The plasma etching method of claim 8, wherein the plasma etching is performed by using a plasma etching apparatus including a processing chamber in which a lower electrode for mounting the substrate to be processed thereon and an upper electrode disposed to face the lower electrode, by applying a first high frequency power for plasma generation to the upper or the lower electrode while applying a second high frequency power for ion induction to the lower electrode, wherein a frequency of the second high frequency power is lower than that of the first high frequency power, and the second high frequency power applied to the lower electrode is set to be equal to or lower than about 0.42 W/cm².

17. A plasma etching apparatus comprising:
a processing chamber for accommodating therein a semiconductor substrate to be processed;
a processing gas supply unit for supplying an etching gas into the processing chamber;
a plasma generating unit for converting the etching gas supplied from the processing gas supply unit into a plasma, thereby plasma processing the semiconductor substrate; and
a control unit for controlling the plasma etching method of claim 1 to be carried out in the processing chamber.

18. A plasma etching apparatus comprising:
a processing chamber for accommodating therein a semiconductor substrate to be processed;
a processing gas supply unit for supplying an etching gas into the processing chamber;
a plasma generating unit for converting the etching gas supplied from the processing gas supply unit into a plasma, thereby plasma processing the semiconductor substrate; and
a control unit for controlling the plasma etching method of claim 2 to be carried out in the processing chamber.

19. A computer-readable storage medium for storing therein a computer executable control program, wherein the control program controls the plasma processing apparatus to perform the plasma etching method of claim 1.

20. A computer-readable storage medium for storing therein a computer executable control program, wherein the control program controls the plasma processing apparatus to perform the plasma etching method of claim 2.
